(19) United States
(12) Patent Application Publication
(10) Pub. No.: US 2025/0196288 A1
(43) Pub. Date: Jun. 19, 2025

(54) METHOD FOR RELEASING SUBSTRATE, METHOD FOR POLISHING SUBSTRATE, SUBSTRATE POLISHING APPARATUS, SUBSTRATE PROCESSING APPARATUS, CONTROL APPARATUS, CONTROL METHOD, AND CONTROL PROGRAM

(71) Applicant: EBARA CORPORATION, Tokyo (JP)

(72) Inventors: Osamu NABEYA, Tokyo (JP); Yuichi KATO, Tokyo (JP)

(21) Appl. No.: 18/975,994

(22) Filed: Dec. 10, 2024

(30) Foreign Application Priority Data
Dec. 13, 2023 (JP) 2023-210130

(51) Int. Cl. B24B 37/34; B23Q 3/08

(52) U.S. Cl. CPC B24B 37/345; B23Q 3/088

(57) ABSTRACT

Provided is a method for releasing a substrate adsorbed to a first surface of an elastic film included in a substrate holding apparatus of a substrate polishing apparatus,
a plurality of concentric pressure chambers being formed between a top ring body included in the substrate holding apparatus and a second surface of the elastic film, the method including:
a first step of supplying fixed-amount gas to two or more pressure chambers among the plurality of pressure chambers to pressurize the elastic film; and
a second step of sequentially depressurizing the plurality of pressure chambers from outer pressure chambers.

### CROSS-REFERENCE TO RELATED APPLICATIONS

This application claims the benefit of Japanese Priority Patent Application JP 2023-210130 filed on Dec. 13, 2023, the entire contents of which are incorporated herein by reference.

### BACKGROUND

### Technical Field

The present disclosure relates to a method for releasing a substrate, a method for polishing a substrate, a substrate polishing apparatus, a substrate processing apparatus, a control apparatus, a control method, and a control program.

### Related Art

In a chemical mechanical polishing (CMP) apparatus, a substrate is polished by being rotated by a polishing head and pressed against a polishing pad while a polishing liquid is supplied to the polishing pad on a rotating polishing table. The substrate is held by a membrane (elastic film) provided in the polishing head, and the substrate is pressed against the polishing pad by a pressurized fluid being supplied into a pressure chamber of the membrane. When the polishing of the substrate is completed, the polishing head releases holding of the substrate by the membrane, remove (releases) the substrate, and delivers the substrate to a transport apparatus. As such a CMP apparatus, for example, JP 2020-199623 A is known.

### PRIOR ART

### Patent literature

[Patent literature 1] JP2020-199623A

An object of the present disclosure is to release a substrate from an elastic film.

### SUMMARY

As examples, the following solutions are provided.
[1] A method for releasing a substrate adsorbed to a first surface of an elastic film included in a substrate holding apparatus of a substrate polishing apparatus,
a plurality of concentric pressure chambers being formed between a top ring body included in the substrate holding apparatus and a second surface of the elastic film, the method comprising:
a first step of supplying fixed-amount gas to two or more pressure chambers among the plurality of pressure chambers to pressurize the elastic film; and
a second step of sequentially depressurizing the plurality of pressure chambers from outer pressure chambers.
[2] The method according to [1], wherein none of the two or more pressure chambers is an outermost pressure chamber.
[3] The method according to [2], wherein the outmost pressure chamber is depressurized in the second step while the fixed-amount gas is supplied to the two or more pressure chambers in the first step.
[4] The method according to any one of [1] to [3], wherein in the first step, the fixed-amount gas is supplied from a single fixed-amount gas supply apparatus to the two or more pressure chambers.
[5] The method according to any one of [1 to [5], wherein
the first step includes opening a first valve provided between each of the two or more pressure chambers and a fixed-amount gas supply apparatus,
the second step includes opening a second valve provided between each of the plurality of pressure chambers and a pressure adjustment apparatus, and
in the second step, in a case where each of the two or more pressure chambers is depressurized, first, the first valve is closed and then the second valve is opened.
[6] The method according to any one of [1] to [5], wherein
in the first step, the fixed-amount gas is supplied from a chamber to the two or more pressure chambers, and
the method comprising a step of generating a negative pressure in the chamber is provided between the first step and the second step, and
in the second step, the two or more pressure chambers are depressurized by the chamber being connected to the two or more pressure chambers.
[7] The method according to any one of [1] to [6], further comprising a third step of supplying the fixed-amount gas to one or more pressure chambers among the two or more pressure chambers in a case where the substrate is not released even if a certain pressure chamber is depressurized in the second step.
[8] A method for polishing a substrate using a substrate holding apparatus including a top ring body and an elastic film,
a first surface of the elastic film being capable of adsorbing the substrate,
a plurality of concentric pressure chambers being formed between the top ring body and a second surface of the elastic film, the method comprising:
a first step of adsorbing the substrate to the first surface of the elastic film by depressurizing at least one of the plurality of pressure chambers in a state where a surface to be adsorbed of the substrate is in contact with the first surface of the elastic film;
a second step of polishing a surface to be polished of the substrate while bringing the surface to be polished of the substrate into contact with a polishing member and pressurizing at least one of the plurality of pressure chambers;
a third step of releasing the surface to be polished of the substrate from the polishing member and supplying fixed-amount gas to two or more pressure chambers among the plurality of pressure chambers to pressurize the elastic film; and
a fourth step of sequentially depressurizing the plurality of pressure chambers from outer pressure chambers to release the substrate from the first surface of the elastic film.
[9] The method according to [8], wherein
in the second step, a pressure adjustment apparatus pressurizes at least one of the plurality of pressure chambers with a first pressure, and
in the third step, pressurizes the elastic film with a second pressure lower than the first pressure.
[10] The method according to [8] or [9], wherein
in the first step, the pressure adjustment apparatus depressurizes at least one of the plurality of pressure chambers,
in the third step, the fixed-amount gas is supplied from a chamber to the two or more pressure chambers,
the method comprises a step of generating a negative pressure in the chamber is provided between the third step and the fourth step,
in the fourth step, the two or more pressure chambers are depressurized by the chamber being connected to the two or more pressure chambers, and
a stress to be applied to the substrate by the depressurization in the fourth step is smaller than a stress to be applied to the substrate by the depressurization in the first step.
[11] A substrate polishing apparatus comprising:
a top ring body;
an elastic film having a first surface capable of adsorbing a substrate, and a second surface forming a plurality of concentric pressure chambers between the second surface and the top ring body;
a polishing member that polishes the adsorbed substrate;
a fixed-amount gas supply apparatus capable of supplying fixed-amount gas to two or more pressure chambers among the plurality of pressure chambers;
first switching means for switching whether or not to allow the fixed-amount gas supply apparatus to communicate with each of the two or more pressure chambers;
a pressure adjustment apparatus capable of individually controlling pressures of the plurality of pressure chambers;
second switching means for switching whether or not to allow the pressure adjustment apparatus to communicate with each of the plurality of pressure chambers; and
a control apparatus that controls the fixed-amount gas supply apparatus, the first switching means, the pressure adjustment apparatus and the second switching means so that the fixed-amount gas supply apparatus supplies the fixed-amount gas to the two or more pressure chambers and then the pressure adjustment apparatus sequentially depressurizes the plurality of pressure chambers from outer pressure chambers in order to release the substrate adsorbed to the first surface of the elastic film.
[12] The substrate polishing apparatus according to [11], wherein
the fixed-amount gas supply apparatus includes:
   a cylinder, and
   a piston that divides the cylinder into an upper space and a lower space, and
a fixed-amount gas in the lower space of the cylinder is supplied by the piston moving downward.
[13] The substrate polishing apparatus according to [11], wherein the fixed-amount gas supply apparatus has a constant volume chamber to be pressurized by the pressure adjustment apparatus.
[14] A substrate processing apparatus comprising:
the substrate polishing apparatus according to any one of [11] to [13];
a substrate cleaning apparatus that cleans the substrate polished by the substrate polishing apparatus; and
a substrate drying apparatus that dries the substrate cleaned by the substrate cleaning apparatus.
[15] A control apparatus that controls a substrate polishing apparatus including:
a top ring body;
an elastic film having a first surface capable of adsorbing a substrate, and a second surface forming a plurality of concentric pressure chambers between the second surface and the top ring body;
a polishing member that polishes the adsorbed substrate;
a fixed-amount gas supply apparatus capable of supplying fixed-amount gas to two or more pressure chambers among the plurality of pressure chambers;
first switching means for switching whether or not to allow the fixed-amount gas supply apparatus to communicate with each of the two or more pressure chambers;
a pressure adjustment apparatus capable of individually controlling pressures of the plurality of pressure chambers; and
second switching means for switching whether or not to allow the pressure adjustment apparatus to communicate with each of the plurality of pressure chambers,
the control apparatus controlling the fixed-amount gas supply apparatus, the first switching means, the pressure adjustment apparatus and the second switching means so that the fixed-amount gas supply apparatus supplies the fixed-amount gas to the two or more pressure chambers and then the pressure adjustment apparatus sequentially depressurizes the plurality of pressure chambers from outer pressure chambers in order to release a substrate adsorbed to the first surface of the elastic film.
[16] A control program for controlling a substrate polishing apparatus including:
a top ring body;
an elastic film having a first surface capable of adsorbing a substrate, and a second surface forming a plurality of concentric pressure chambers between the second surface and the top ring body;
a polishing member that polishes the adsorbed substrate;
a fixed-amount gas supply apparatus capable of supplying fixed-amount gas to two or more pressure chambers among the plurality of pressure chambers;
first switching means for switching whether or not to allow the fixed-amount gas supply apparatus to communicate with each of the two or more pressure chambers;
a pressure adjustment apparatus capable of individually controlling pressures of the plurality of pressure chambers; and
second switching means for switching whether or not to allow the pressure adjustment apparatus to communicate with each of the plurality of pressure chambers, the control program causing a computer to function as
means for controlling the fixed-amount gas supply apparatus, the first switching means, the pressure adjustment apparatus and the second switching means so that the fixed-amount gas supply apparatus supplies the fixed-amount gas to the two or more pressure chambers and then the pressure adjustment apparatus sequentially depressurizes the plurality of pressure chambers from outer pressure chambers in order to release a substrate adsorbed to the first surface of the elastic film.
[17] A control method for controlling a substrate polishing apparatus including: a top ring body;
an elastic film having a first surface capable of adsorbing a substrate, and a second surface forming a plurality of concentric pressure chambers between the second surface and the top ring body;
a polishing member that polishes the adsorbed substrate;
a fixed-amount gas supply apparatus capable of supplying fixed-amount gas to two or more pressure chambers among the plurality of pressure chambers;
first switching means for switching whether or not to allow the fixed-amount gas supply apparatus to communicate with each of the two or more pressure chambers;
a pressure adjustment apparatus capable of individually controlling pressures of the plurality of pressure chambers; and
second switching means for switching whether or not to allow the pressure adjustment apparatus to communicate with each of the plurality of pressure chambers,
the control method controlling the fixed-amount gas supply apparatus, the first switching means, the pressure adjustment apparatus and the second switching means so that the fixed-amount gas supply apparatus supplies the fixed-amount gas to the two or more pressure chambers and then the pressure adjustment apparatus sequentially depressurizes the plurality of pressure chambers from outer pressure chambers in order to release a substrate adsorbed to the first surface of the elastic film.

It is possible to release a substrate from an elastic film.

### BRIEF DESCRIPTION OF DRAWINGS

FIG. 1 is a schematic configuration diagram of a substrate processing apparatus 100;

FIG. 2 is a schematic perspective view of a substrate polishing apparatus 3;

FIG. 3 is a view schematically illustrating a schematic cross section of a top ring 10;

FIG. 4A1 is a schematic view illustrating a configuration example of a fixed-amount gas supply apparatus 14;

FIG. 4A2 is a schematic view illustrating a configuration example of the fixed-amount gas supply apparatus 14;

FIG. 4B is a schematic view illustrating another configuration example of the fixed-amount gas supply apparatus 14;

FIG. 5 is a flowchart indicating a processing step of the substrate polishing apparatus 3;

FIG. 6 is a view for explaining the processing step of the substrate polishing apparatus 3;

FIG. 7 is a view for explaining the processing step of the substrate polishing apparatus 3 subsequent to FIG. 6;

FIG. 8 is a view for explaining the processing step of the substrate polishing apparatus 3 subsequent to FIG. 7;

FIG. 9 is a schematic view for explaining a state after polishing and before start of releasing;

FIG. 10 is a schematic view for explaining a state at the start of releasing;

FIG. 11 is a schematic view for explaining a state in which a pressure chamber A5 is depressurized;

FIG. 12A is a schematic view for explaining a state in which a pressure chamber A4 is further depressurized;

FIG. 12B is a schematic view for explaining a state in which a substrate W is released;

FIG. 13 is a flowchart indicating a step for releasing the substrate W adsorbed to a membrane 13;

FIG. 14 is a view for explaining a step for releasing the substrate W;

FIG. 15 is a view for explaining a step for releasing the substrate W subsequent to FIG. 14;

FIG. 16 is a view for explaining a step for releasing the substrate W subsequent to FIG. 15;

FIG. 17 is a view for explaining a step for releasing the substrate W subsequent to FIG. 16;

FIG. 18 is a view for explaining a step for releasing the substrate W subsequent to FIG. 17;

FIG. 19 is a flowchart indicating a step for releasing the substrate W adsorbed to the membrane 13;

FIG. 20 is a view for explaining a step for releasing the substrate W;

FIG. 21 is a view for explaining a step for releasing the substrate W subsequent to FIG. 20;

FIG. 22 is a view for explaining a step for releasing the substrate W subsequent to FIG. 21;

FIG. 23 is a view for explaining a step for releasing the substrate W subsequent to FIG. 22:

FIG. 24 is a view for explaining a step for releasing the substrate W subsequent to FIG. 23;

FIG. 25 is a view for explaining a step for releasing the substrate W subsequent to FIG. 24;

FIG. 26 is a view schematically illustrating a schematic cross section of the top ring 10 according to a modification;

FIG. 27 is a flowchart indicating a step for releasing the substrate W adsorbed to the membrane 13;

FIG. 28 is a view for explaining a step for releasing the substrate W; and

FIG. 29 is a view for explaining a step for releasing the substrate W subsequent to FIG. 28.

### DETAILED DESCRIPTION

Embodiments of the present invention will be specifically described below with reference to the drawings.

### First Embodiment

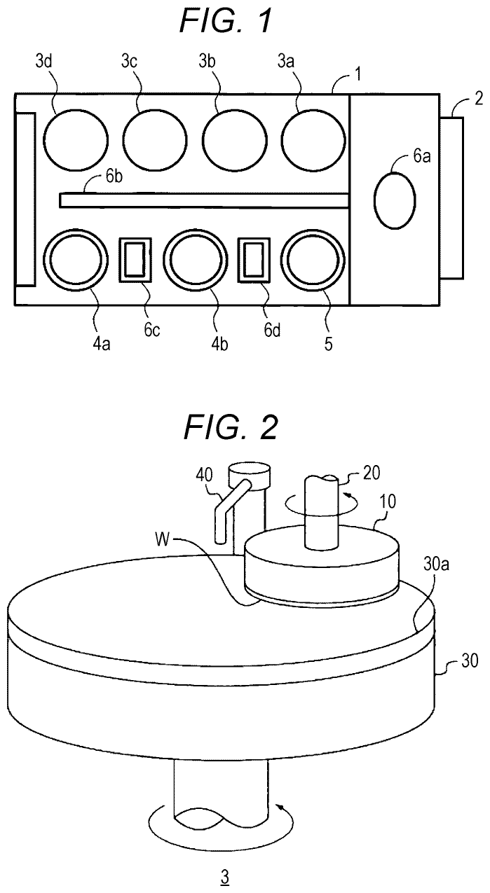

FIG. 1 is a schematic configuration diagram of a substrate processing apparatus 100. The substrate processing apparatus 100 is, for example, a CMP apparatus, and includes a substantially rectangular housing 1 and a load port 2 disposed adjacent to the housing 1.

A substrate cassette (not illustrated) that keeps a plurality of substrates W in stock is placed on the load port 2. Examples of the substrate W include a semiconductor wafer. However, the substrate W to be processed is not limited to a semiconductor wafer, and may be another type of substrate to be used for manufacturing a semiconductor device, such as a glass substrate and a ceramic substrate. In addition, a semiconductor film, a metal film, or the like, is formed on at least one surface of the substrate W.

The substrate processing apparatus 100 includes one or more (four in FIG. 1) substrate polishing apparatuses 3a to 3d (in a case where they are not particularly distinguished, they may be collectively referred to as a “substrate polishing apparatus 3”), one or more (two in FIG. 1) substrate cleaning apparatuses 4a and 4b (in a case where they are not particularly distinguished, they may be collectively referred to as a “substrate cleaning apparatus 4”), and one or more (one in FIG. 1) substrate drying apparatuses 5, which are disposed inside the housing 1.

As an example, the substrate polishing apparatuses 3a to 3d are disposed along one side of the housing 1 in a longitudinal direction. The substrate cleaning apparatuses 4a and 4b and the substrate drying apparatus 5 are disposed along the other side of the housing 1 in the longitudinal direction.

The substrate polishing apparatus 3 polishes a surface of the substrate W. More specifically, the substrate polishing apparatus 3 supplies slurry onto the substrate W while rotating the substrate W, and polishes the surface of the substrate W by pressing a polishing member (not illustrated) against the surface of the substrate W. Polishing waste or slurry may remain on the substrate W after polishing. A detailed configuration example of the substrate polishing apparatus 3 will be described later.

The substrate cleaning apparatus 4 cleans the surface of the substrate W after polishing. More specifically, the substrate cleaning apparatus 4 cleans the surface of the substrate W by pressing a substrate cleaning tool (not illustrated in FIG. 1) against the surface of the substrate W while rotating the substrate W.

The substrate drying apparatus 5 dries the surface of the substrate W after cleaning. For example, the substrate drying apparatus 5 is a spin drying apparatus and dries the substrate W by rotating the substrate W at a high speed by a centrifugal force while drying the substrate W by ejecting isopropyl alcohol vapor from an injection nozzle to the rotating substrate W.

In addition, the substrate processing apparatus 100 includes substrate transport apparatuses 6a to 6d (in a case where they are not particularly distinguished, they may be collectively referred to as a “substrate transport apparatus 6”), which are disposed inside the housing 1.

The substrate transport apparatus 6a is disposed adjacent to the load port 2. The substrate transport apparatus 6a receives the substrate W before processing from the load port 2 and passes the substrate W to the substrate transport apparatus 6b, and receives the substrate W after processing from the substrate transport apparatus 6b.

The substrate transport apparatus 6b extends in the longitudinal direction at the central portion of the housing 1. The substrate transport apparatus 6b receives the substrate W before processing from the substrate transport apparatus 6a and transports the substrate W to any one of the substrate polishing apparatuses 3a to 3d, receives the substrate W after polishing from the substrate polishing apparatuses 3a to 3d and passes the substrate W to the substrate transport apparatus 6c, or receives the substrate W after drying from the substrate transport apparatus 6d and passes the substrate W to the substrate transport apparatus 6a.

The substrate transport apparatus 6c is disposed between the substrate cleaning apparatuses 4a and 4b. The substrate transport apparatus 6c receives the polished substrate W from the substrate transport apparatus 6b and transports the substrate W to either the substrate cleaning apparatus 4a or 4b, or receives the cleaned substrate W from the substrate cleaning apparatus 4a and transports the substrate W to the substrate cleaning apparatus 4b.

The substrate transport apparatus 6d is disposed between the substrate cleaning apparatus 4b and the substrate drying apparatus 5. The substrate transport apparatus 6d receives the cleaned substrate W from the substrate cleaning apparatus 4b and transports the substrate W to the substrate drying apparatus 5, or receives the substrate W after drying from the substrate drying apparatus 5 and passes the substrate W to the substrate transport apparatus 6b.

Note that the arrangement of the substrate polishing apparatus 3, the substrate cleaning apparatus 4, the substrate drying apparatus 5, and the substrate transport apparatus 6 is merely an example. One or more substrate transport apparatuses 6 may be provided so that the substrate W can be transported in the order of the substrate polishing apparatus 3, the substrate cleaning apparatus 4, and the substrate drying apparatus 5.

FIG. 2 is a schematic perspective view of the substrate polishing apparatus 3. The substrate polishing apparatus 3 includes a top ring 10 (substrate holding apparatus) that holds the substrate W to be polished, a top ring shaft 20 having a lower end connected to the top ring 10, a polishing table 30 provided with a polishing pad 30a (polishing member) on its upper surface, and a nozzle 40 that supplies slurry. Outline of the operation of the substrate polishing apparatus 3 is as follows.

The top ring 10 receives the substrate W from the substrate transport apparatus (FIG. 1). Then, a lifting mechanism (not illustrated) lowers the top ring shaft 20. As a result, a lower surface of the substrate W comes into contact with the polishing pad 30a of the polishing table 30. Then, the nozzle 40 supplies the slurry onto the polishing pad 30a. Further, a motor (not illustrated) rotates the top ring shaft 20, and another motor rotates the polishing table 30. As a result, the substrate W and the polishing table 30 rotate in a state where the lower surface of the substrate W is in contact with the polishing pad 30a, thereby the substrate W is polished.

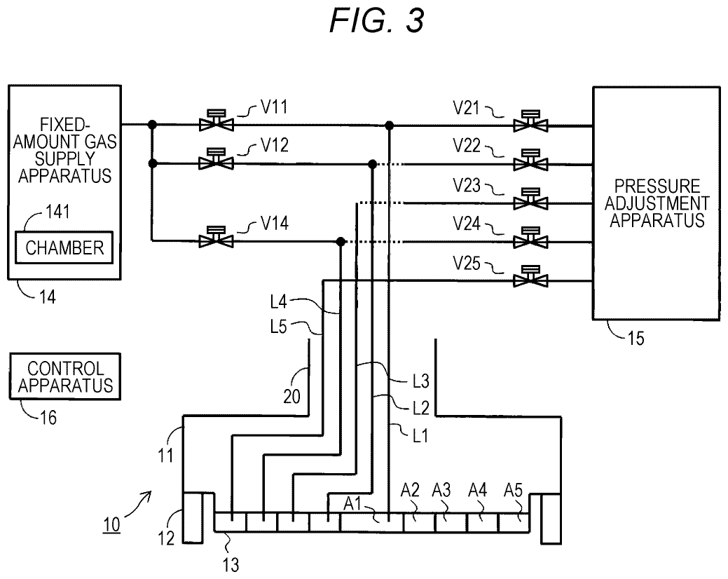

FIG. 3 is a view schematically illustrating a cross section of the top ring 10. The top ring 10 includes a top ring body 11 (also referred to as a carrier or a base plate), a retainer ring 12, a flexible membrane 13 (elastic film), a fixed-amount gas supply apparatus 14, a pressure adjustment apparatus 15, a control apparatus 16, and the like. Note that the fixed-amount gas supply apparatus 14, the pressure adjustment apparatus 15, and/or the control apparatus 16 may constitute the top ring 10, or may be an apparatus different from the top ring 10.

The retainer ring 12 is an annular member provided on an outer peripheral portion of the top ring body 11. A peripheral edge of the held substrate W is surrounded by the retainer ring 12 so that the substrate W does not protrude from the top ring 10 during polishing. The retainer ring 12 may be a single member or may have a double ring configuration including an inner ring and an outer ring provided outside the inner ring.

The membrane 13 has a circular shape and can adsorb and hold the substrate W with a lower surface of the membrane 13. The membrane 13 is attached below the top ring body 11 and inside the retainer ring 12. Specifically, the membrane 13 is provided with a plurality of partition walls directed upward, and the partition walls are fixed to the top ring body 11. A plurality of pressure chambers released by the partition walls are formed between the top ring body 11 and an upper surface of the membrane 13. In the specific example of FIG. 3, a circular pressure chamber A1 is formed at the center, and four annular pressure chambers A2 to A5 are formed outside the pressure chamber A1. These pressure chambers have a common center position.

One end of pipes L1 to L5 communicate with the pressure chambers A1 to A5, respectively. The other end of the pipe L1 is branched, one is connected to the fixed-amount gas supply apparatus 14 via a valve V11, and the other is connected to the pressure adjustment apparatus 15 via a valve V21. The same applies to the pipes L2 and L4. The pipes L3 and L5 are not connected to the fixed-amount gas supply apparatus 14, but are connected only to the pressure adjustment apparatus 15 via the valves L23 and L25, respectively. However, the pipes L3 and L5 may also be connected to the pressure adjustment apparatus 15 similarly to the pipes L1, L2, and L4.

The fixed-amount gas supply apparatus 14 can supply a fixed-amount gas to the pressure chambers A1, A2, and A4 via the pipes L1, L2, and L4 in combination with the valves V11, V12, and V14. More specifically, the fixed-amount gas supply apparatus 14 includes a chamber 141, and the fixed-amount gas is supplied from the chamber 141. The fixed-amount gas supply apparatus 14 only needs to able to supply the fixed-amount gas to at least two of the pressure chambers A1 to A5, and thus may not communicate with the other pressure chambers. A specific configuration example of the fixed-amount gas supply apparatus 14 will be described later.

The pressure adjustment apparatus 15 can individually adjust pressures of the pressure chambers A1 to A5 by combining with the valves V21 to V25. In other words, the pressure adjustment apparatus 15 can pressurize, depressurize, or open the pressure chambers A1 to A5 to the atmosphere via the pipes L1 to L5 according to control of the control apparatus 16.

The control apparatus 16 controls the valves V11, V12, V14, and V21 to V25, the fixed-amount gas supply apparatus 14, and the pressure adjustment apparatus 15. Each function by the control apparatus 16 may be implemented by a processor executing a predetermined program. The valves V11, V12, and V14 can be said to be means for switching whether or not to allow the fixed-amount gas supply apparatus 14 to communicate with each of the pressure chambers A1, A2, and A4. In addition, the valves V21 to V25 can be said to be means for switching whether or not to allow the pressure adjustment apparatus 15 to communicate with the pressure chambers A1 to A5.

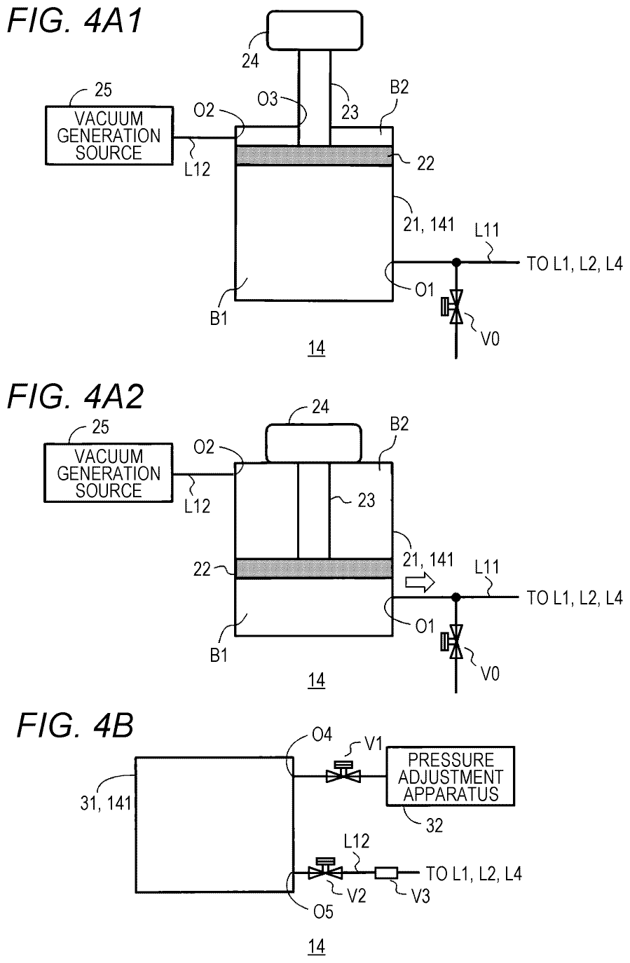

FIGS. 4A1 and 4A2 are schematic views illustrating a configuration example of the fixed-amount gas supply apparatus 14. The fixed-amount gas supply apparatus 14 includes a cylinder 21 as the chamber 141, a piston 22, a piston rod 23, a weight 24, and a vacuum generation source 25.

The cylinder 21 extends in a vertical direction in a columnar shape, and has a hollow inside. An outer periphery of the piston 22 is in contact with an inner surface of the cylinder 21 and can move up and down. The piston rod 23 extends in the vertical direction and passes through an opening O3 provided on an upper surface of the cylinder 21. The piston 22 is connected to a lower end of the piston rod 23, and the weight 24 is fixed to an upper end.

The piston 22 divides the inside of the cylinder 21 into a lower space B1 and an upper space B2. The outer periphery of the piston 22 is in contact with the inner surface of the cylinder 21, and thus, gas hardly moves back and forth between the lower space B1 and the upper space B2.

An opening O1 is provided at a position corresponding to the lower space B1 of the cylinder 21. A pipe L11 is connected to the opening O1. The pipe L11 is connected to the pipes L1, L2, and L4 (see FIG. 3) via V11, V12, and V14, respectively. The pipe L11 is provided with a valve V0 at a branch destination, and the lower space B1 can be opened to the atmosphere by opening the valve V0.

In addition, an opening O2 is provided at a position corresponding to the upper space B2 of the cylinder 21. A pipe L12 is connected to the opening O2. The vacuum generation source 25 is connected to the pipe L12, and the upper space B2 can be depressurized or opened to the atmosphere via the pipe L12.

As a result of the vacuum generation source 25 depressurizing the upper space B2 in a state where the valve V0 is opened, the cylinder 21 rises, and a fixed-amount gas is stored in the lower space B1 (FIG. 4A1). Then, if the upper space B2 is opened to the atmosphere in a state where the valve V0 is closed, the weight 24 moves downward by gravity, and the fixed-amount gas in the lower space B1 is supplied from the pipe L11 (FIG. 4A2). The valve V0 and the vacuum generation source 25 are controlled by the control apparatus 16 in FIG. 3. It is also possible to supply the fixed-amount gas by, for example, pressurizing the piston 22 downward from the vacuum generation source 25 without providing the weight 24. In any case, the fixed-amount gas in the lower space B1 is supplied as a result of the piston 22 moving downward.

FIG. 4B is a schematic view illustrating another configuration example of the fixed-amount gas supply apparatus 14. The fixed-amount gas supply apparatus 14 includes a constant volume chamber 31 as the chamber 141 and a pressure adjustment apparatus 32. The pressure adjustment apparatus 32 is desirably also used as the pressure adjustment apparatus 15 illustrated in FIG. 3.

The constant volume chamber 31 is provided with an opening O4, and is connected to the pressure adjustment apparatus 32 via the valve V1. The constant volume chamber 31 is provided with an opening O5, and the pipe L12 connected to pipes L1, L2, and L4 (see FIG. 3) is connected via the valve V2.

The valves V1, V2 and the pressure adjustment apparatus 32 are controlled by the control apparatus 16 in FIG. 3. The pressure adjustment apparatus 32 pressurizes the constant volume chamber 31 to about 50 hPa in a state where the valve V1 is opened and the valve V2 is closed, and thereafter, the valve V1 is closed, whereby a fixed-amount gas at a high pressure is stored in the constant volume chamber 31. As a result of the valve V1 being closed and the valve V2 being opened, the fixed-amount gas in the constant volume chamber 31 is supplied from the pipe L12. In order to lower a flow rate of the supplied gas, a needle valve V3 may be provided in the pipe L12.

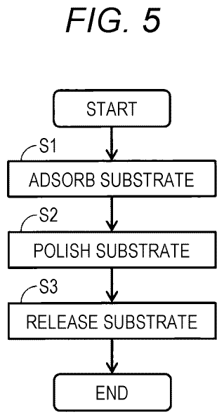

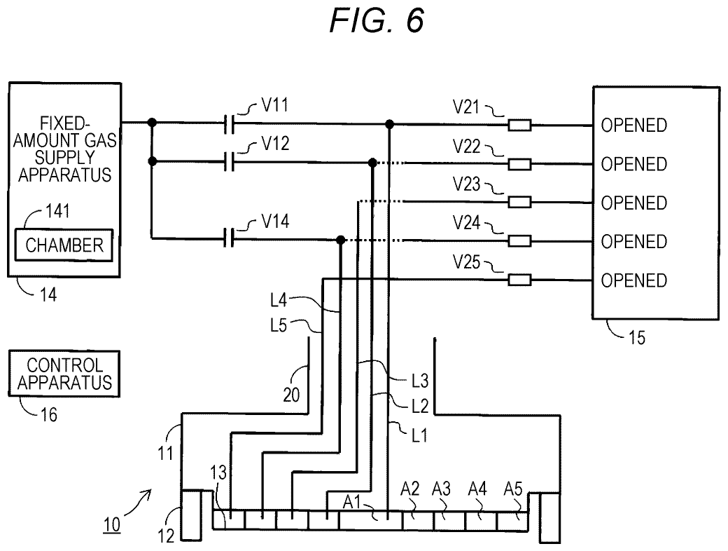

FIG. 5 is a flowchart indicating a processing step of the substrate polishing apparatus 3. Before substrate polishing is performed, that is, in a standby state in which the top ring 10 does not hold the substrate W, as illustrated in FIG. 6, the valves V11, V12, and V14 are closed, the valves V21 to V25 are opened, and the pressure adjustment apparatus 15 is opened to the atmosphere. Thus, the pressure chambers A1 to A5 are opened to the atmosphere.

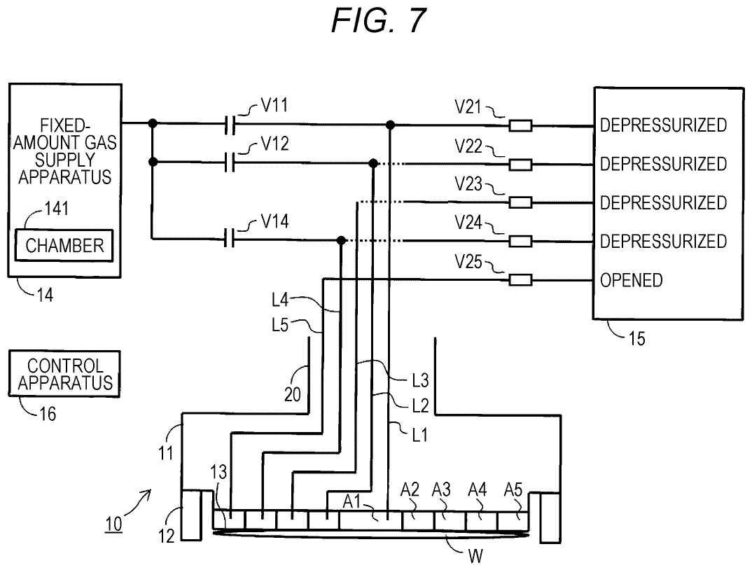

First, the substrate polishing apparatus 3 adsorbs and holds the substrate W transported by the substrate transport apparatus 6 (FIG. 1), to the membrane 13 of the top ring 10 (step S1). Specifically, as illustrated in FIG. 7, in a state where the upper surface of the substrate W is in contact with the lower surface of the membrane 13, at least one of the pressure chambers A1 to A5 (the pressure chambers A1 to A4 in the example of FIG. 7) is depressurized to about −500 hPa from the pressure adjustment apparatus 15. As a result, the substrate W is adsorbed to the lower surface of the membrane 13.

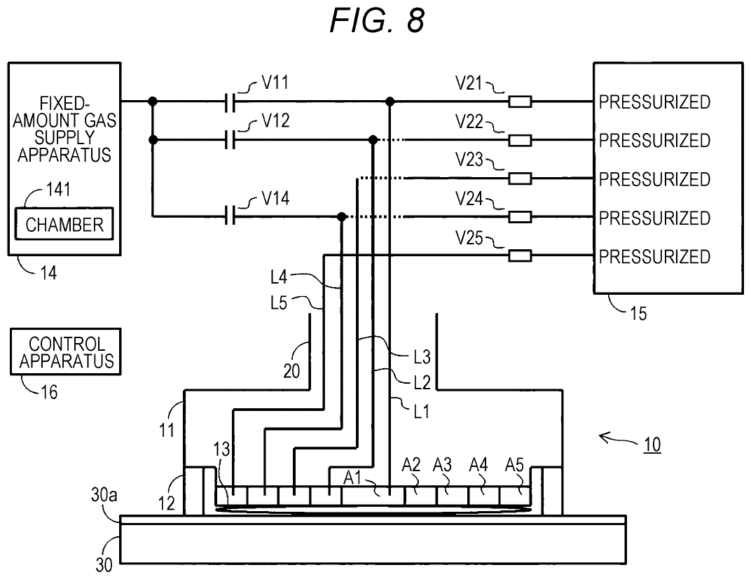

Next, the substrate polishing apparatus 3 lowers the adsorbed and held substrate W, brings the lower surface of the substrate W into contact with the polishing pad 30a of the polishing table 30, and polishes the substrate (step S2). Specifically, as illustrated in FIG. 8, at least one of the pressure chambers A1 to A5 (the pressure chambers A1 to A5 in the example of FIG. 8) is pressurized to about 50 to 500 hPa from the pressure adjustment apparatus 15. As a result, the lower surface of the substrate W is polished.

Then, the substrate polishing apparatus 3 releases the substrate W adsorbed to the membrane 13 (step S3).

As an example of a method for releasing the substrate W, it is conceivable to pressurize the pressure chambers A1 to A5 from the pressure adjustment apparatus 15. However, in such a method, the pressure from the pressure adjustment apparatus 15 is too large, a large stress is applied to the substrate W, and the substrate W may be damaged in some cases.

As another example, it is conceivable to release the substrate W by injecting nitrogen gas or water from the side of the substrate W. However, in such a method, a posture of the falling substrate W becomes unstable due to injection, and the substrate W may be damaged at the time of releasing.

Thus, in the present embodiment, the substrate W adsorbed to the membrane 13 is released as follows.

First, a releasing method according to the present embodiment will be schematically described.

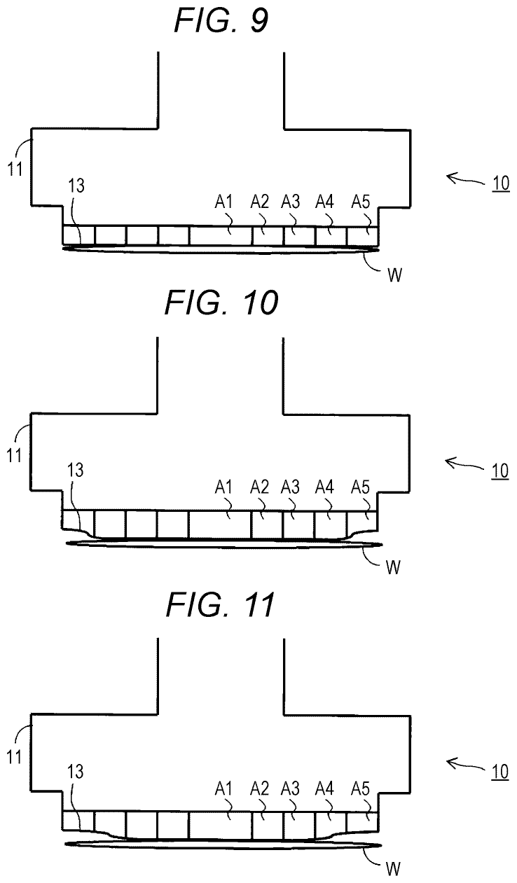

FIG. 9 is a schematic view for explaining a state after polishing and before start of releasing. The upper surface of the substrate W is adsorbed to the membrane 13. However, the lower surface of the substrate W is released from the polishing table 30 (FIG. 8).

FIG. 10 is a schematic view for explaining a state at the start of releasing. The fixed-amount gas is supplied from the fixed-amount gas supply apparatus 14 to two or more of the pressure chambers A1 to A5, and the membrane 13 is pressurized to about 1 to 3 hPa. This pressure is lower than the pressure at the time of polishing the substrate (step S2 in FIG. 5). By supplying an appropriate amount of gas from the single fixed-amount gas supply apparatus 14 to two or more of the pressure chambers A1 to A5, the same pressure can be applied to these pressure chambers, so that it is possible to prevent a large stress from being applied to the substrate W. As illustrated, an end portion of the substrate W is peeled off from the membrane 13, but the substrate W still remains adsorbed to the membrane 13.

Note that in this step, one or more arbitrary pressure chambers A1 to A5 (all the pressure chambers A1 to A5 in some cases) may be pressurized, but the outermost pressure chamber A5 does not have to be pressurized. This is because the end of the substrate W is in contact with the atmosphere and is easily peeled off from the membrane 13. Thereafter, the pressure chambers A1 to A5 are sequentially depressurized from the outer pressure chambers A5 to A1.

FIG. 11 is a schematic view for explaining a state in which the pressure chamber A5 is depressurized. By depressurizing the pressure chamber A5, a region (outer peripheral portion) of the membrane 13 corresponding to the pressure chamber A5 is attracted to the top ring body 11. As a result, the substrate W is further peeled off from the membrane 13.

The pressure in the pressure chamber A5 at this time is about −50 kPa to −10 kPa. This pressure may be about the same as the pressure at the time of adsorption of the substrate (step S1 in FIG. 5), but a stress of the substrate W is preferably reduced by low vacuum in consideration of a case where the membrane 13 is sticked to the substrate W.

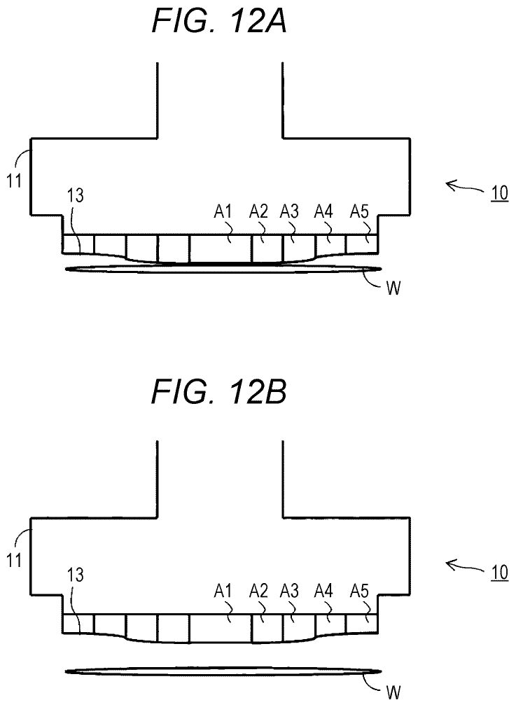

FIG. 12A is a schematic view for explaining a state where pressure chamber A4 is further depressurized. By depressurizing the pressure chamber A4, a region of the membrane 13 corresponding to the pressure chambers A5 and A4 is attracted to the top ring body 11. As a result, the substrate W is further peeled off from the membrane 13. Then, an area where the substrate W is adsorbed to the membrane 13 becomes sufficiently small, and the substrate W is released from the membrane 13 and falls by its own weight (FIG. 12B).

In a case where the substrate W is not released from the membrane 13 even if the pressure chamber A4 is depressurized, it is only necessary to sequentially depressurize the pressure chambers A3 to A1 until the substrate W is released.

Note that in FIG. 10, in a case where the outermost pressure chamber A5 is not pressurized, the pressure chamber A5 may be depressurized while the fixed-amount gas is supplied to any one or more of the pressure chambers A1 to A4.

According to such a method, a stress to be applied to the substrate W is reduced, and it is not necessary to inject nitrogen gas or water to the substrate W. This will be more specifically described below.

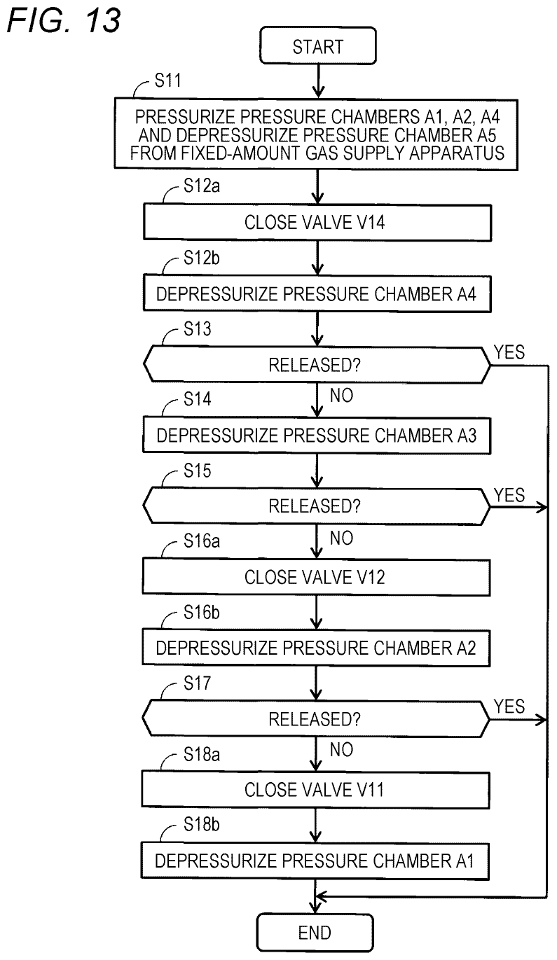

FIG. 13 is a flowchart indicating a step for releasing the substrate W adsorbed to the membrane 13. It is assumed that the polishing of the substrate W is completed and the lower surface of the substrate W is released from the polishing table 30. In addition, it is assumed that the fixed-amount gas supply apparatus 14 is ready to supply the fixed-amount gas. For example, in a case of the fixed-amount gas supply apparatus 14 illustrated in FIG. 4A1, the fixed-amount gas is stored in the lower space B1, and the valve V0 is closed. In a case of the fixed-amount gas supply apparatus 14 illustrated in FIG. 4B, the fixed-amount gas at a high pressure is stored in the constant volume chamber 31, and the valves V1 and V2 are closed.

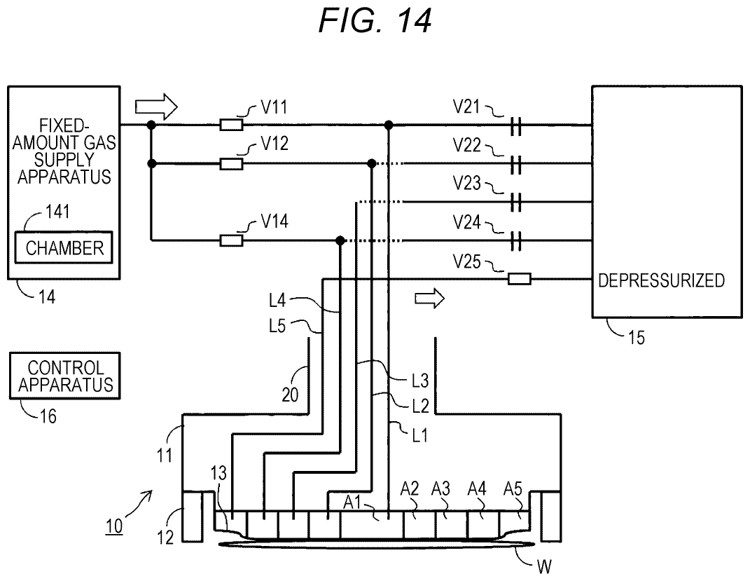

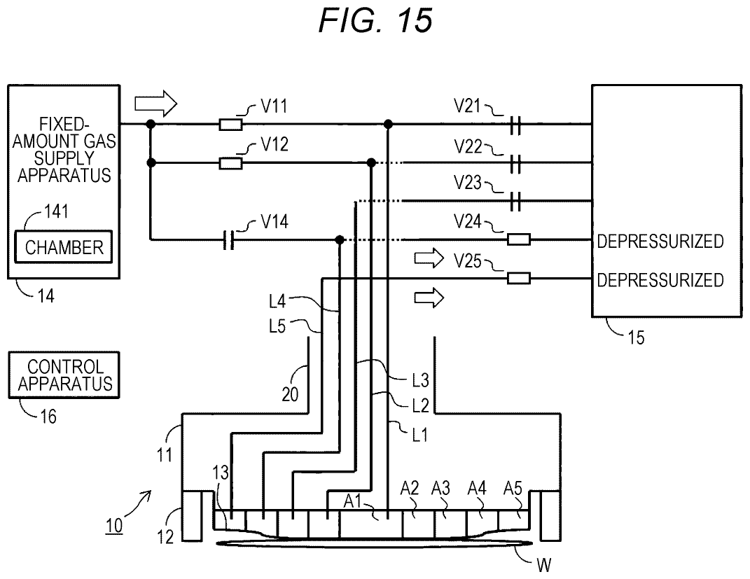

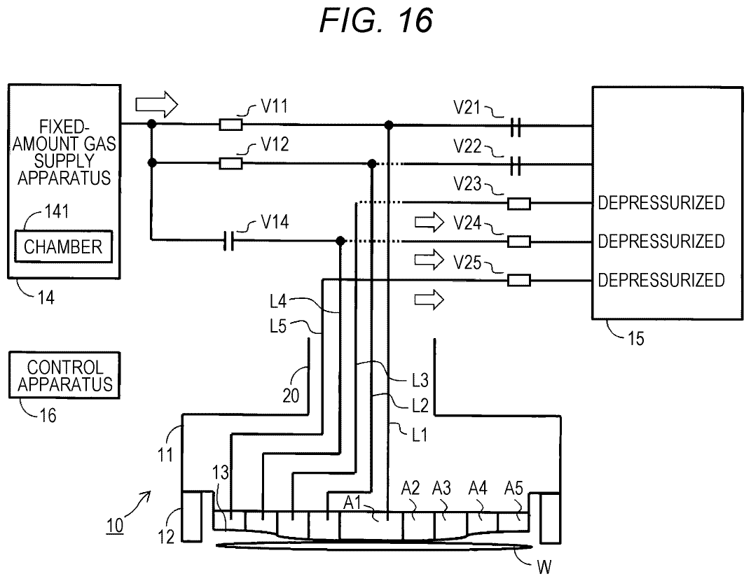

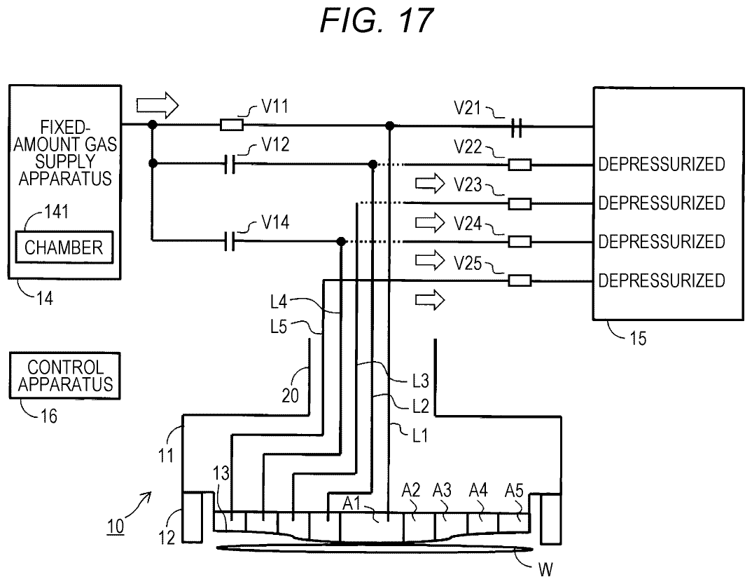

First, as illustrated in FIG. 14, the valves V11, V12, and V14 are opened and the valves V21 to V24 are closed, and the fixed-amount gas is supplied from the fixed-amount gas supply apparatus 14 to the pressure chambers A1, A2, and A4. As a specific example, the upper space B2 of the fixed-amount gas supply apparatus 14 illustrated in FIG. 4A1 is opened to the atmosphere. Alternatively, the valve V2 of the fixed-amount gas supply apparatus 14 illustrated in FIG. 4B is opened. As a result, the membrane 13 is pressurized. At the same time, or before or after the above, the valve V25 is opened, and the pressure adjustment apparatus 15 depressurizes the outermost pressure chamber A5 (step S11).

As a result, at least the outer peripheral portion of the substrate W is expected to be peeled off from the membrane 13.

Subsequently, as illustrated in FIG. 15, the valve V14 is closed (step S12a), and then the valve V24 is opened, and the pressure adjustment apparatus 15 depressurizes the pressure chamber A4 located on the inner side of the pressure chamber A5 (step S12b). The reason for this order is that if the pressure chamber A4 is depressurized in a state where the valve V14 is opened, the other pressure chambers A1 to A3 are also depressurized at the same time. The fixed-amount gas supply apparatus 14 continues to pressurize the pressure chambers A1 and A2.

If the substrate W is released from the membrane 13 (step S13: Yes) by this, the releasing processing ends. Even if the substrate W is not released (step S13: No), it is expected that at least part of the inner side of the outer peripheral portion of the substrate W is peeled off from the membrane 13.

In a case where the substrate W is not released from the membrane 13, as illustrated in FIG. 16, the valve V23 is opened, and the pressure adjustment apparatus 15 depressurizes the pressure chamber A3 located on the inner side of the pressure chamber A4 (step S14). The fixed-amount gas supply apparatus 14 continues to pressurize the pressure chambers A1 and A2.

If the substrate W is released from the membrane 13 (step S15: Yes) by this, the releasing processing ends. Even if the substrate W is not released (step S15: No), it is expected that at least part of the substrate W further inside is peeled off from the membrane 13.

In a case where the substrate W is not released from the membrane 13, as illustrated in FIG. 17, the valve V12 is closed (step S16a), and then the valve V22 is opened, and the pressure adjustment apparatus 15 depressurizes the pressure chamber A2 located on the inner side of the pressure chamber A3 (step S16b). Note that the fixed-amount gas supply apparatus 14 continues to pressurize the pressure chamber A1.

If the substrate W is released from the membrane 13 (step S17: Yes) by this, the releasing processing ends. Even if the substrate W is not released (step S17: No), it is expected that at least part of the substrate W further inside is peeled off from the membrane 13.

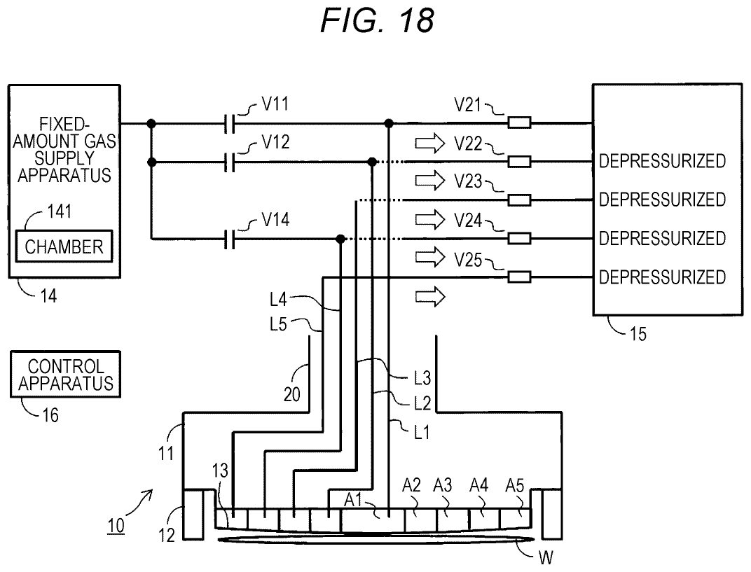

In a case where the substrate W is not released from the membrane 13, as illustrated in FIG. 18, the valve V11 is closed (step S18a), and then the valve V21 is opened, and the pressure adjustment apparatus 15 depressurizes the pressure chamber A1 located one inside of the pressure chamber A2 (step S18b). As a result, the inside of the substrate W is further peeled off from the membrane 13, and the substrate W is released from the membrane 13.

The opening and closing of the valves V11, V12, V14, and V21 to V25 and the operation of the fixed-amount gas supply apparatus 14 and the pressure adjustment apparatus 15 described above may be controlled by the control apparatus 16.

As described above, in the present embodiment, the membrane 13 is pressurized by the fixed-amount gas being supplied from the fixed-amount gas supply apparatus 14. It is therefore possible to release the substrate W from the membrane 13 without applying a large stress to the substrate W and without injecting nitrogen gas or water to the substrate W.

### Second Embodiment

In the first embodiment described above, the membrane 13 is depressurized (steps S12b, S14, and S16b in FIG. 13) by the pressure adjustment apparatus 15. On the other hand, in a second embodiment described below, the membrane 13 is depressurized using the fixed-amount gas supply apparatus 14 as a negative pressure generation source. Hereinafter, description common to the first embodiment will be omitted or simplified, and differences will be mainly described.

As described in the first embodiment, the pressure adjustment apparatus 15 depressurizes the pressure chamber to about −500 hPa in order to adsorb and hold the substrate (step S1 in FIG. 5). This pressure may possibly apply a stress to the substrate W in some cases. On the other hand, in a case where the fixed-amount gas supply apparatus 14 is used as a negative pressure generation source, the pressure chamber is depressurized only to about −1 to 3 hPa. Thus, the stress to be applied to the substrate W can be further reduced.

In order to use the fixed-amount gas supply apparatus 14 as a negative pressure generation source, it is only necessary to generate a negative pressure in the chamber 141.

For example, in the fixed-amount gas supply apparatus 14 illustrated in FIGS. 4A1 and 4A2, by the vacuum generation source 25 depressurizing the upper space B2 of the cylinder 21 in a state where the valves V0 and the valves V11 to V14 provided in the pipes L1 to L4 connected to the pipe L11 are closed, a negative pressure is generated in the lower space B1 of the cylinder 21.

Alternatively, in the fixed-amount gas supply apparatus 14 illustrated in FIG. 4B, by the pressure adjustment apparatus 32 depressurizing the constant volume chamber 31 in a state where the valve V2 is closed and the valve V1 is opened, a negative pressure is generated in the constant volume chamber 31.

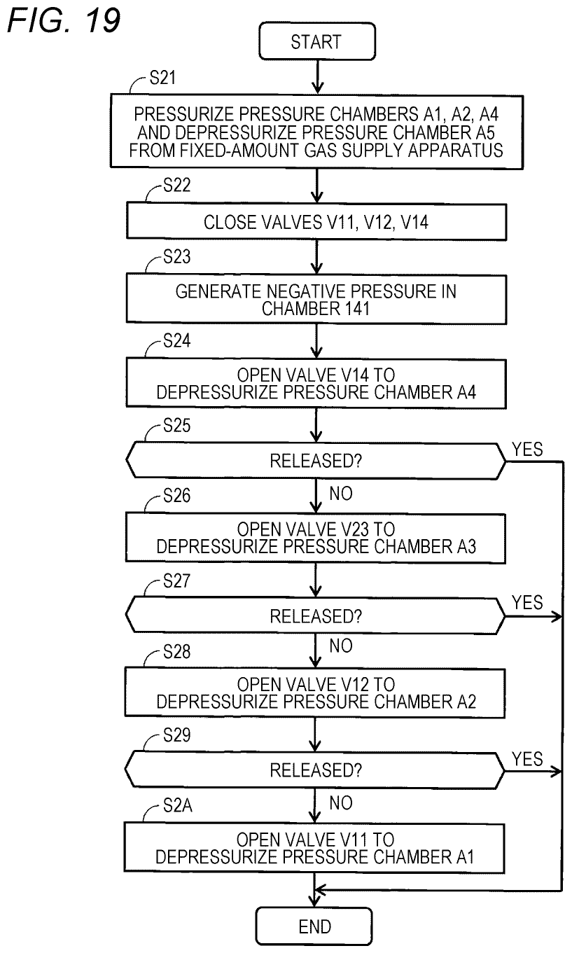

FIG. 19 is a flowchart indicating a step for releasing the substrate W adsorbed to the membrane 13. It is assumed that the polishing of the substrate W is completed and the lower surface of the substrate W is released from the polishing table 30. In addition, it is assumed that the fixed-amount gas supply apparatus 14 is ready to supply the fixed-amount gas. For example, in a case of the fixed-amount gas supply apparatus 14 illustrated in FIG. 4A1, the fixed-amount gas is stored in the lower space B1, and the valve V0 is closed. In a case of the fixed-amount gas supply apparatus 14 illustrated in FIG. 4B, the fixed-amount gas at a high pressure is stored in the constant volume chamber 31, and the valves V1 and V2 are closed.

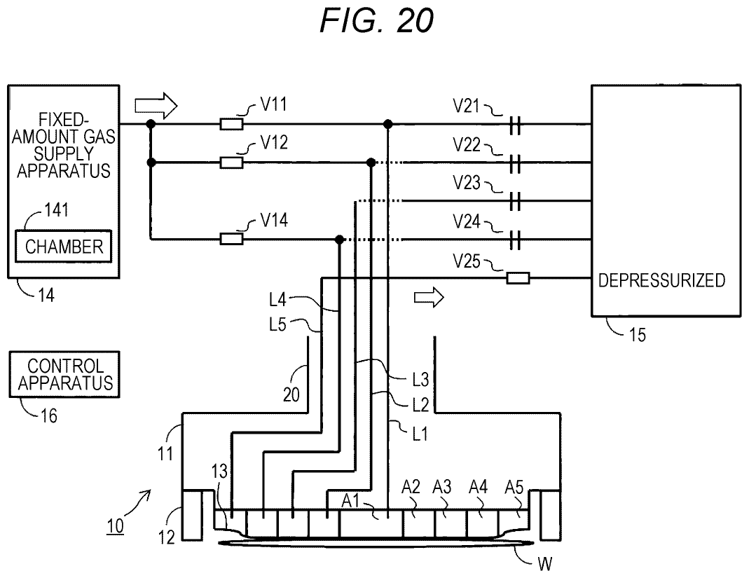

First, as illustrated in FIG. 20, the valves V11, V12, and V14 are opened and the valves V21 to V24 are closed, and the fixed-amount gas is supplied from the fixed-amount gas supply apparatus 14 to the pressure chambers A1, A2, and A4. As a result, the membrane 13 is pressurized. At the same time, or before or after the above, the valve V25 is opened, and the pressure adjustment apparatus 15 depressurizes the outermost pressure chamber A5 (step S21).

As a result, at least the outer peripheral portion of the substrate W is expected to be peeled off from the membrane 13.

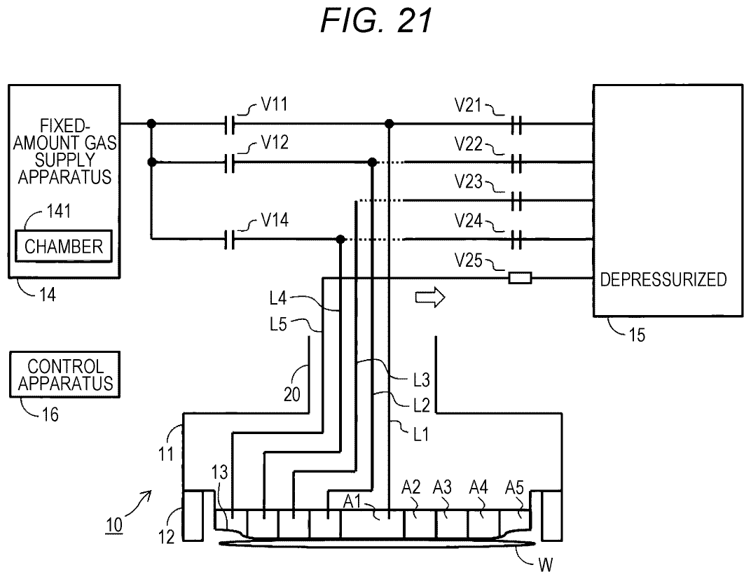

Subsequently, as illustrated in FIG. 21, the valves V11, V12, and V14 are closed (step S22). As a result, all of the pressure chambers A1, A2, and A4 are blocked from the fixed-amount gas supply apparatus 14. Then, a negative pressure is generated in the chamber 141 of the fixed-amount gas supply apparatus 14 (step S23). As a result, the fixed-amount gas supply apparatus 14 functions as a negative pressure generation source.

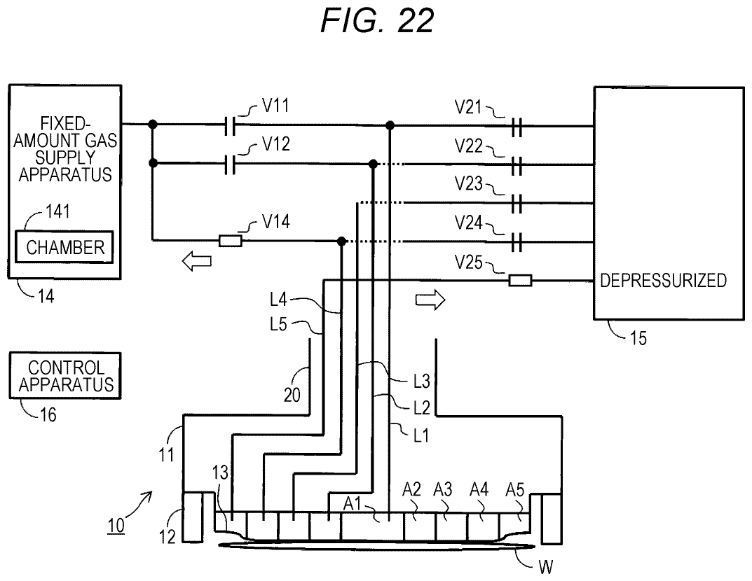

Next, as illustrated in FIG. 22, the valve V14 is opened. As a result, the pressure chamber A4 communicates with the fixed-amount gas supply apparatus 14 serving as the negative pressure generation source, and the pressure chamber A4 is depressurized (step S24). Even if the valve V14 is opened, the valves V11 and V12 are closed, and thus, the pressures in the pressure chambers A1 and A2 hardly fluctuate.

If the substrate W is released from the membrane 13 (step S25: Yes) by this, the releasing processing ends. Even if the substrate W is not released (step S25: No), it is expected that at least part of the inner side of the outer peripheral portion of the substrate W is peeled off from the membrane 13.

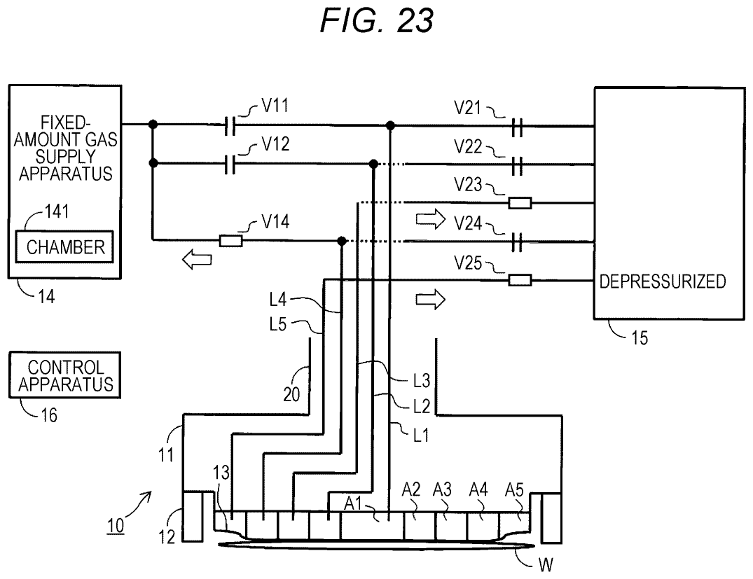

In a case where the substrate W is not released from the membrane 13 (step S25: No), as illustrated in FIG. 23, the valve V23 is opened, and the pressure adjustment apparatus 15 depressurizes the pressure chamber A3 located on the inner side of the pressure chamber A4 (step S26). In this manner, the pressure chamber A3 to which the fixed-amount gas supply apparatus 14 is not connected is depressurized by the pressure adjustment apparatus 15.

If the substrate W is released from the membrane 13 (step S27: Yes) by this, the releasing processing ends. Even if the substrate W is not released (step S27: No), it is expected that at least part of the inner side of the outer peripheral portion of the substrate W is peeled off from the membrane 13.

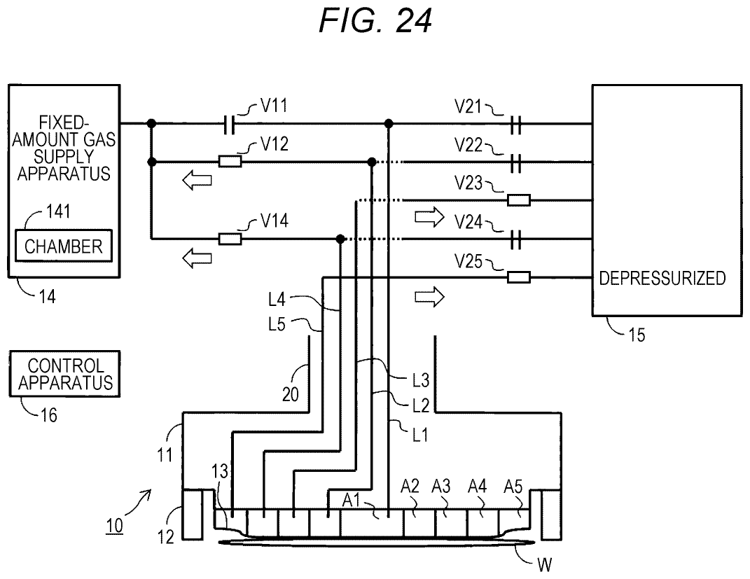

In a case where the substrate W is not released from the membrane 13 (step S27: No), as illustrated in FIG. 24, the valve V12 is opened to allow the pressure chamber A2 to communicate with the fixed-amount gas supply apparatus 14, thereby the pressure chamber A2 is depressurized (step S28). Note that even if the valve V12 is opened, the valve V1 is closed, and thus, the pressure in the pressure chamber A1 hardly fluctuates.

If the substrate W is released from the membrane 13 (step S29: Yes) by this, the releasing processing ends. Even if the substrate W is not released (step S29: No), it is expected that at least part of the inner side of the outer peripheral portion of the substrate W is peeled off from the membrane 13.

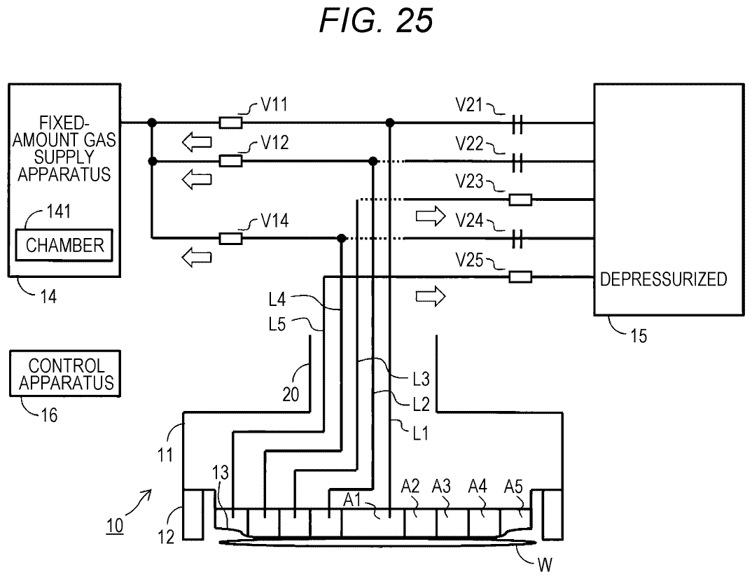

In a case where the substrate W is not released from the membrane 13 (step S29: No), as illustrated in FIG. 25, the valve V11 is opened to allow the pressure chamber A1 to communicate with the fixed-amount gas supply apparatus 14, thereby the pressure chamber A1 is depressurized (step S2A). As a result, the inside of the substrate W is further peeled off from the membrane 13, and the substrate W is released from the membrane 13.

As described above, in the present embodiment, the pressure chamber to which the fixed-amount gas supply apparatus 14 is connected is depressurized not by the pressure adjustment apparatus 15 but by the fixed-amount gas supply apparatus 14 as a negative pressure generation source. Thus, the stress to be applied to the substrate W can be further reduced.

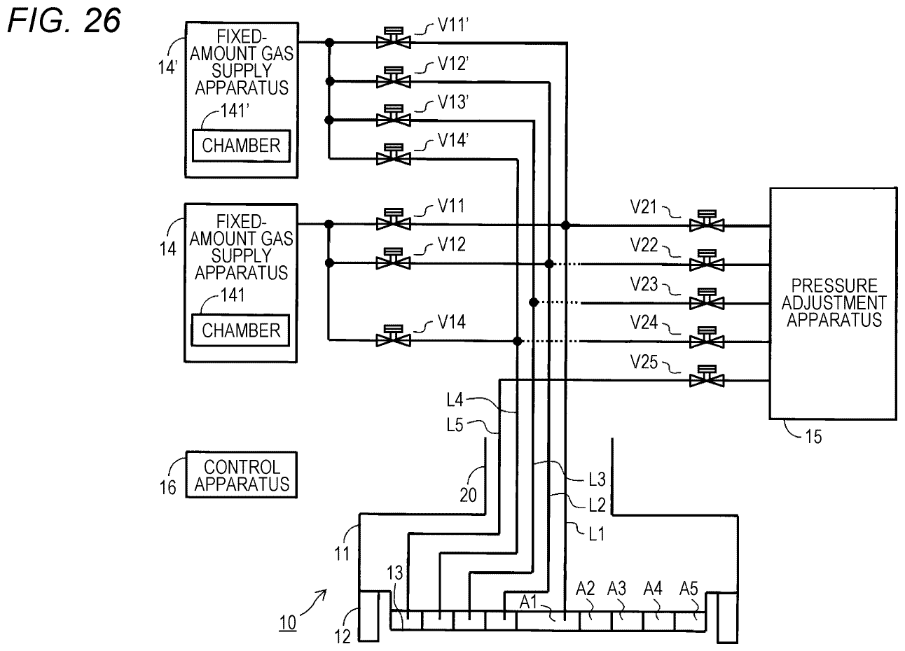

Note that in the present embodiment, pressurization (step S21 in FIG. 18) and depressurization (same steps S24, S28, S2A) are performed using one fixed-amount gas supply apparatus 14. On the other hand, as illustrated in FIG. 26, a fixed-amount gas supply apparatus 14′ for depressurization may be provided separately from the fixed-amount gas supply apparatus 14 for pressurization. In a case where the fixed-amount gas supply apparatus 14 for pressurization is connected only to the pressure chambers A1, A2, and A4, the fixed-amount gas supply apparatus 14′ for depressurization may be similarly connected only to the pressure chambers A1, A2, and A4, but may be connected to other pressure chambers. In particular, the fixed-amount gas supply apparatus 14′ for depressurization may also be connected to the pressure chamber A3, and the depressurization may also be performed from the fixed-amount gas supply apparatus 14′. By providing the fixed-amount gas supply apparatuses separately, it is possible to achieve appropriate pressures. In particular, in a case of the fixed-amount gas supply apparatus 14 (FIGS. 4A1 and 4A2) using the cylinder 21, a pressure to be generated changes depending on a volume of the cylinder 21, and thus, the volume of the cylinder 21 can be optimized.

### Third Embodiment

As described in the first embodiment and the second embodiment, when the pressure chambers are sequentially depressurized from the outer pressure chambers, the substrate W may not be released (for example, step S17 in FIG. 13: No, step S29 in FIG. 18: No). In the third embodiment to be described next, in a case where the substrate W is not released even if a certain pressure chamber is depressurized, pressurization is performed again from the fixed-amount gas supply apparatus 14. Hereinafter, the description common to the first and second embodiments will be omitted or simplified, and differences will be mainly described.

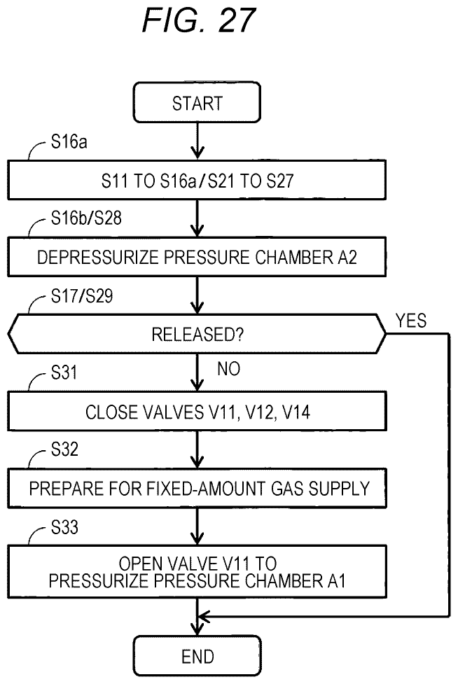

FIG. 27 is a flowchart indicating a step for releasing the substrate W adsorbed to the membrane 13. It is assumed that the pressure chamber A2 is pressurized through steps S11 to S16a in FIG. 13 or steps S21 to S27 in FIG. 18 (steps S16b and S28), but the substrate W is not released from the membrane 13 (steps S17 and S29: No).

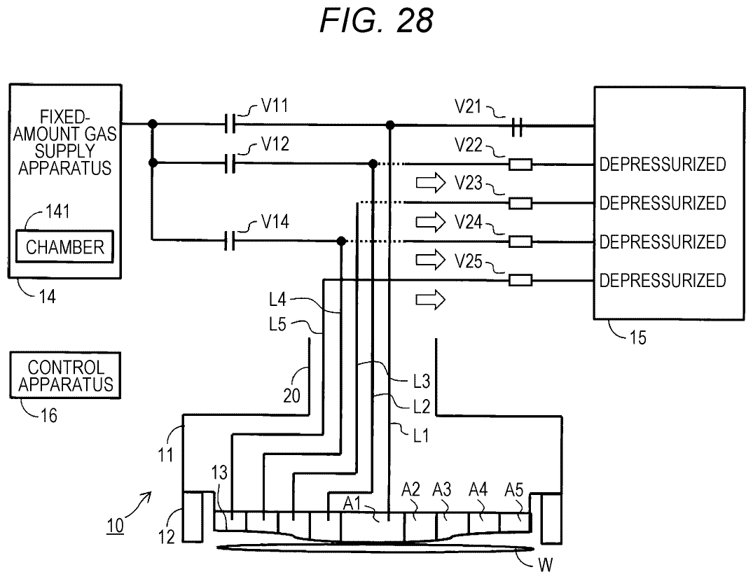

In this case, as illustrated in FIG. 28, the valves V11, V12, and V14 are closed (step S31).

Then, the fixed-amount gas supply apparatus 14 prepares for supplying the fixed-amount gas (step S32). For example, in a case of the fixed-amount gas supply apparatus 14 illustrated in FIGS. 4A1 and 4A2, the valve V0 is opened, and the vacuum generation source 25 depressurizes the upper space B2. As a result, the cylinder 22 rises. Thereafter, by the valve V0 being closed, the fixed-amount gas is stored in the lower space B1. In a case of the fixed-amount gas supply apparatus 14 illustrated in FIG. 4B, the valve V1 is opened, the valve V2 is closed, and the pressure adjustment apparatus 32 pressurizes the constant volume chamber 31. Thereafter, by the valve V1 being closed, the fixed-amount gas is stored in the constant volume chamber 31.

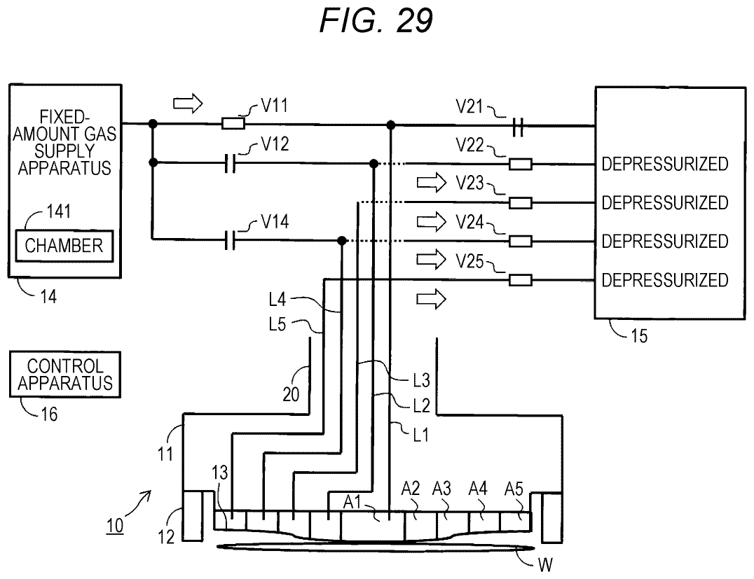

Next, as illustrated in FIG. 29, the pressure chamber A1 is pressurized in a state where the valve V11 is opened (step S33). As a result, the center of the membrane 13 swells downward, and the substrate W is released from the membrane 13.

As described above, in the present embodiment, in a case where the substrate W is not released from the membrane 13 even if a certain pressure chamber is depressurized, the fixed-amount gas is supplied to repressurize the membrane 13. As a result, the substrate W can be reliably released from the membrane 13.

It is desirable that the central pressure chamber A1 is pressurized in step S33, but other pressure chambers may be pressurized.

Arbitrary some or all of the functional units described in the present specification may be implemented by a program. The program referred to in the present specification may be distributed by being non-temporarily recorded in a computer-readable recording medium, may be distributed via a communication line (including wireless communication) such as the Internet, or may be distributed in a state of being installed in an arbitrary terminal.

Based on the above description, a person skilled in the art may be able to conceive additional effects and various modifications of the present invention, but aspects of the present invention are not limited to the individual embodiments described above. For example, an invention in which only part of each embodiment is extracted or an invention in which a plurality of embodiments are combined is naturally assumed. Various additions, modifications, and partial deletions can be made without departing from the conceptual idea and spirit of the present invention derived from the content defined in the claims and equivalents thereof.

For example, what is described herein as one apparatus (or a member, the same applies hereinafter) (including what is drawn in the drawings as one apparatus) may be implemented by a plurality of apparatuses. Conversely, what is described herein as a plurality of apparatuses (including what is drawn in the drawings as a plurality of apparatuses) may be implemented by one apparatus. Alternatively, some or all of the means and functions included in a certain apparatus may be included in another apparatus.

In addition, not all the matters described in the present specification are essential requirements. In particular, matters described in the present specification and not described in the claims can be regarded as any additional matters.

In addition, the term “means” in the present specification and claims means hardware (or a function implemented by hardware) itself and does not include a human (or mental activity of a human) unless otherwise specified.

It should be noted that the applicant of the present invention is merely aware of the invention disclosed in JP 2020-199623 A, and the present invention is not necessarily intended to solve the problem in the invention disclosed in the document. The problem to be solved by the present invention should be recognized in consideration of the entire specification. For example, in the present specification, in a case where there is description that a predetermined effect is exhibited by a specific configuration, it can be said that the problem of reversing the predetermined effect is solved. However, such a specific configuration is not necessarily essential requirements.

### REFERENCE SIGNS LIST

100 Substrate processing apparatus
1 Housing
2 Load port
3, 3a to 3d Substrate polishing apparatus
4, 4a, 4b Substrate cleaning apparatus
5 Substrate drying apparatus
6, 6a to 6d Substrate transport apparatus
10 Top ring
11 Top ring body
12 Retainer ring
13 Membrane
14 Fixed-amount gas supply apparatus
141 Chamber
15 Pressure adjustment apparatus
16 Control apparatus
20 Top ring shaft
21 Cylinder
22 Piston
23 Piston rod
24 Weight
25 Vacuum generation source
30 Polishing table
31 Constant volume chamber
32 Pressure adjustment apparatus
30a Polishing pad
40 Nozzle
A1 to A5 Pressure chamber

1. A method for releasing a substrate adsorbed to a first surface of an elastic film included in a substrate holding apparatus of a substrate polishing apparatus,
a plurality of concentric pressure chambers being formed between a top ring body included in the substrate holding apparatus and a second surface of the elastic film, the method comprising:
a first step of supplying fixed-amount gas to two or more pressure chambers among the plurality of pressure chambers to pressurize the elastic film; and
a second step of sequentially depressurizing the plurality of pressure chambers from outer pressure chambers.

2. The method according to claim 1, wherein none of the two or more pressure chambers is an outermost pressure chamber.

3. The method according to claim 2, wherein the outmost pressure chamber is depressurized in the second step while the fixed-amount gas is supplied to the two or more pressure chambers in the first step.

4. The method according to claim 1, wherein in the first step, the fixed-amount gas is supplied from a single fixed-amount gas supply apparatus to the two or more pressure chambers.

5. The method according to claim 1, wherein
the first step includes opening a first valve provided between each of the two or more pressure chambers and a fixed-amount gas supply apparatus,
the second step includes opening a second valve provided between each of the plurality of pressure chambers and a pressure adjustment apparatus, and
in the second step, in a case where each of the two or more pressure chambers is depressurized, first, the first valve is closed and then the second valve is opened.

6. The method according to claim 1, wherein
in the first step, the fixed-amount gas is supplied from a chamber to the two or more pressure chambers, and
the method comprising a step of generating a negative pressure in the chamber is provided between the first step and the second step, and
in the second step, the two or more pressure chambers are depressurized by the chamber being connected to the two or more pressure chambers.

7. The method according to claim 1, further comprising a third step of supplying the fixed-amount gas to one or more pressure chambers among the two or more pressure chambers in a case where the substrate is not released even if a certain pressure chamber is depressurized in the second step.

8. A method for polishing a substrate using a substrate holding apparatus including a top ring body and an elastic film,
a first surface of the elastic film being capable of adsorbing the substrate,
a plurality of concentric pressure chambers being formed between the top ring body and a second surface of the elastic film, the method comprising:
a first step of adsorbing the substrate to the first surface of the elastic film by depressurizing at least one of the plurality of pressure chambers in a state where a surface to be adsorbed of the substrate is in contact with the first surface of the elastic film;
a second step of polishing a surface to be polished of the substrate while bringing the surface to be polished of the substrate into contact with a polishing member and pressurizing at least one of the plurality of pressure chambers;
a third step of releasing the surface to be polished of the substrate from the polishing member and supplying fixed-amount gas to two or more pressure chambers among the plurality of pressure chambers to pressurize the elastic film; and
a fourth step of sequentially depressurizing the plurality of pressure chambers from outer pressure chambers to release the substrate from the first surface of the elastic film.

9. The method according to claim 8, wherein
in the second step, a pressure adjustment apparatus pressurizes at least one of the plurality of pressure chambers with a first pressure, and
in the third step, pressurizes the elastic film with a second pressure lower than the first pressure.

10. The method according to claim 8, wherein
in the first step, the pressure adjustment apparatus depressurizes at least one of the plurality of pressure chambers,
in the third step, the fixed-amount gas is supplied from a chamber to the two or more pressure chambers,
the method comprises a step of generating a negative pressure in the chamber is provided between the third step and the fourth step,
in the fourth step, the two or more pressure chambers are depressurized by the chamber being connected to the two or more pressure chambers, and
a stress to be applied to the substrate by the depressurization in the fourth step is smaller than a stress to be applied to the substrate by the depressurization in the first step.

11. A substrate polishing apparatus comprising:
a top ring body;
an elastic film having a first surface capable of adsorbing a substrate, and a second surface forming a plurality of concentric pressure chambers between the second surface and the top ring body;
a polishing member that polishes the adsorbed substrate;
a fixed-amount gas supply apparatus capable of supplying fixed-amount gas to two or more pressure chambers among the plurality of pressure chambers;
first switching means for switching whether or not to allow the fixed-amount gas supply apparatus to communicate with each of the two or more pressure chambers;
a pressure adjustment apparatus capable of individually controlling pressures of the plurality of pressure chambers;
second switching means for switching whether or not to allow the pressure adjustment apparatus to communicate with each of the plurality of pressure chambers; and
a control apparatus that controls the fixed-amount gas supply apparatus, the first switching means, the pressure adjustment apparatus and the second switching means so that the fixed-amount gas supply apparatus supplies the fixed-amount gas to the two or more pressure chambers and then the pressure adjustment apparatus sequentially depressurizes the plurality of pressure chambers from outer pressure chambers in order to release the substrate adsorbed to the first surface of the elastic film.

12. The substrate polishing apparatus according to claim 11, wherein
the fixed-amount gas supply apparatus includes:
a cylinder, and
a piston that divides the cylinder into an upper space and a lower space, and
a fixed-amount gas in the lower space of the cylinder is supplied by the piston moving downward.

13. The substrate polishing apparatus according to claim 11, wherein the fixed-amount gas supply apparatus has a constant volume chamber to be pressurized by the pressure adjustment apparatus.

14. A substrate processing apparatus comprising:
the substrate polishing apparatus according to claim 11;
a substrate cleaning apparatus that cleans the substrate polished by the substrate polishing apparatus; and
a substrate drying apparatus that dries the substrate cleaned by the substrate cleaning apparatus.

15. A control apparatus that controls a substrate polishing apparatus including:
a top ring body;
an elastic film having a first surface capable of adsorbing a substrate, and a second surface forming a plurality of concentric pressure chambers between the second surface and the top ring body;
a polishing member that polishes the adsorbed substrate;
a fixed-amount gas supply apparatus capable of supplying fixed-amount gas to two or more pressure chambers among the plurality of pressure chambers;
first switching means for switching whether or not to allow the fixed-amount gas supply apparatus to communicate with each of the two or more pressure chambers;
a pressure adjustment apparatus capable of individually controlling pressures of the plurality of pressure chambers; and
second switching means for switching whether or not to allow the pressure adjustment apparatus to communicate with each of the plurality of pressure chambers,
the control apparatus controlling the fixed-amount gas supply apparatus, the first switching means, the pressure adjustment apparatus and the second switching means so that the fixed-amount gas supply apparatus supplies the fixed-amount gas to the two or more pressure chambers and then the pressure adjustment apparatus sequentially depressurizes the plurality of pressure chambers from outer pressure chambers in order to release a substrate adsorbed to the first surface of the elastic film.

16. A control program for controlling a substrate polishing apparatus including:
a top ring body;
an elastic film having a first surface capable of adsorbing a substrate, and a second surface forming a plurality of concentric pressure chambers between the second surface and the top ring body;
a polishing member that polishes the adsorbed substrate;
a fixed-amount gas supply apparatus capable of supplying fixed-amount gas to two or more pressure chambers among the plurality of pressure chambers;
first switching means for switching whether or not to allow the fixed-amount gas supply apparatus to communicate with each of the two or more pressure chambers;
a pressure adjustment apparatus capable of individually controlling pressures of the plurality of pressure chambers; and
second switching means for switching whether or not to allow the pressure adjustment apparatus to communicate with each of the plurality of pressure chambers, the control program causing a computer to function as
means for controlling the fixed-amount gas supply apparatus, the first switching means, the pressure adjustment apparatus and the second switching means so that the fixed-amount gas supply apparatus supplies the fixed-amount gas to the two or more pressure chambers and then the pressure adjustment apparatus sequentially depressurizes the plurality of pressure chambers from outer pressure chambers in order to release a substrate adsorbed to the first surface of the elastic film.

17. A control method for controlling a substrate polishing apparatus including: a top ring body;
an elastic film having a first surface capable of adsorbing a substrate, and a second surface forming a plurality of concentric pressure chambers between the second surface and the top ring body;
a polishing member that polishes the adsorbed substrate;
a fixed-amount gas supply apparatus capable of supplying fixed-amount gas to two or more pressure chambers among the plurality of pressure chambers;
first switching means for switching whether or not to allow the fixed-amount gas supply apparatus to communicate with each of the two or more pressure chambers;
a pressure adjustment apparatus capable of individually controlling pressures of the plurality of pressure chambers; and
second switching means for switching whether or not to allow the pressure adjustment apparatus to communicate with each of the plurality of pressure chambers,
the control method controlling the fixed-amount gas supply apparatus, the first switching means, the pressure adjustment apparatus and the second switching means so that the fixed-amount gas supply apparatus supplies the fixed-amount gas to the two or more pressure chambers and then the pressure adjustment apparatus sequentially depressurizes the plurality of pressure chambers from outer pressure chambers in order to release a substrate adsorbed to the first surface of the elastic film.
